(19) United States
(12) Patent Application Publication
(10) Pub. No.: US 2018/0295734 A1
(43) Pub. Date: Oct. 11, 2018

(54) Vent Box

(71) Applicant: GE Oil & Gas ESP, Inc., Oklahoma City, OK (US)

(72) Inventor: Lantz Von Tungeln, Oklahoma City, OK (US)

(73) Assignee: GE Oil & Gas ESP, Inc., Oklahoma City, OK (US)

(21) Appl. No.: 16/008,993

(22) Filed: Jun. 14, 2018

Related U.S. Application Data
(62) Division of application No. 14/049,170, filed on Oct. 8, 2013, now abandoned.

(51) Int. Cl. H05K 5/02; E21B 43/12

(52) U.S. Cl. CPC H05K 5/0217; E21B 43/128; H05K 5/0247; H05K 5/0204

(57) ABSTRACT

A vent box for venting gases present on a power cable used to provide power to an electric submersible pumping system includes a front, a back, a plurality of sides, a top and a bottom. The vent box includes one or more upper vents positioned along an upper edge of at least one of the front, the back or the plurality of sides. The vent box further includes one or more lower vents that extend through the bottom. The top includes a weather cap that extends downward from the top to partially conceal the one or more upper vents.

### RELATED APPLICATIONS

This application is a divisional of U.S. patent application Ser. No. 14/049,170 entitled “Vent Box,” filed Oct. 8, 2013, the disclosure of which is herein incorporated by reference.

### FIELD OF THE INVENTION

This invention relates generally to the field of surface equipment for downhole pumping systems, and more particularly, but not by way of limitation, to a vent box for venting downhole gases to the atmosphere.

### BACKGROUND

Electric submersible pumping systems are often used to produce liquids and gases from subterranean wells. The electric submersible pumping system typically includes various surface-based equipment for providing power and control to the pumping system. The surface-based equipment may include transformers, switchboards, variable speed drives, junction boxes, and power cables. A transformer typically provides power through a power cable to the switchboard or variable speed drive and then is connected to a junction box. Power cables then travel from the junction box to the wellhead and down to the downhole motor and other downhole equipment.

During operation of a downhole pumping system, gases from the well may travel up through the cable. These gases are potentially combustible and must therefore be vented to the atmosphere to avoid safety hazards and other problems. In the past, manufacturers have attempted to incorporate valve-based vent systems into junction boxes. These prior art vent boxes have failed to meet regulatory requirements because the mechanical check valves are prone to failure. There is, therefore, a need for an improved vented junction box that safely and reliably vents gases to the atmosphere. It is to these and other deficiencies in the prior art that the preferred embodiments are directed.

### SUMMARY OF THE INVENTION

In one embodiment, the present invention includes a system for providing power to an electric submersible pumping system deployed in a wellbore. The system includes a surface-based power supply, an electric motor deployed in the wellbore, a first power cable connected to the surface-based power supply, a second power cable connected to the electric motor and a vent box connected to the first power cable and to the second power cable. The vent box has a front, a back, a plurality of sides connected to the front and the back, and one or more upper vents positioned along an upper edge of at least one of the front, the back or the plurality of sides. The vent box may also include a bottom connected to the front, the back and the plurality of sides. The vent box further includes a top connected to the front, the back and the plurality of sides. The top includes a weather cap that extends downward from the top to partially conceal the one or more upper vents. The vent box is configured to release gases travelling from the wellbore along and inside the second power cable through the one or more upper vents and one or more lower vents.

In another embodiment, the present invention includes a pumping system that has a surface-based power supply and an electric motor deployed in a wellbore. The pumping system further includes a vent box that has a front, a back, a pair of opposing sides, a bottom, an interior defined by the front, the back and the pair of opposing sides, a plurality of upper vents that place the interior in communication with the atmosphere, and a top connected to the front, the back and the pair of opposing sides. The top at least partially conceals one or more of the plurality of upper vents. The pumping system further includes a first power cable connected to the vent box and the power supply and a second power cable connected to the electric motor and the vent box. The first power cable is placed in electrical connection with the second power cable inside the vent box.

### BRIEF DESCRIPTION OF THE DRAWINGS

FIG. 1 is a side schematic view of a downhole pumping system.

FIG. 2 is a front isometric view of a preferred embodiment of the vent box.

FIG. 3 is a rear isometric view of a preferred embodiment of the vent box of FIG. 2.

FIG. 4 is a bottom view of the vent box of FIG. 2.

FIG. 5 is a front view of the vent box of FIG. 2.

FIG. 6 is a back view of the vent box of FIG. 2.

FIG. 7 is a side view of the vent box of FIG. 2.

### DETAILED DESCRIPTION OF THE PREFERRED EMBODIMENTS

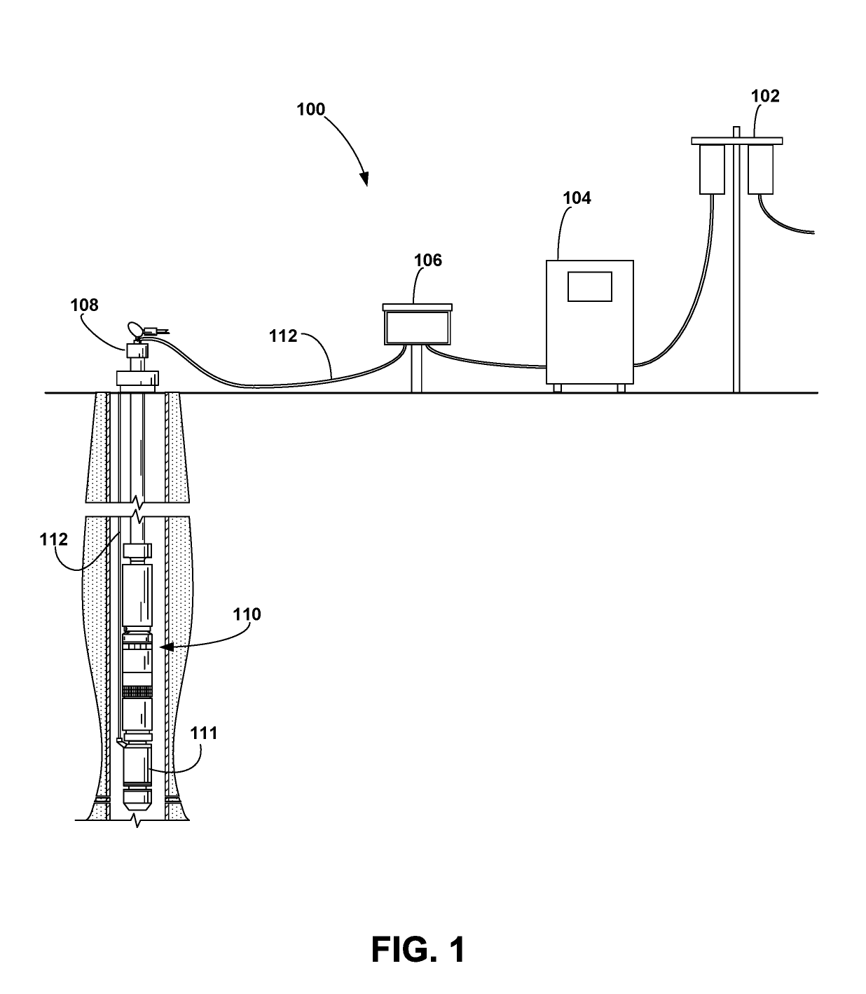

In accordance with a preferred embodiment of the present invention, FIG. 1 shows a side perspective view of a downhole pumping system 100. The downhole pumping system 100 includes one or more transformers 102, a power supply 104, a vent box 106, a wellhead 108, and a downhole pumping system 110. The downhole pumping system 110 includes an electric motor 111 that drives a pumping mechanism when energized. A power cable 112 provides electric power and communication from the power supply 104 to the electric motor 111. In preferred embodiments, the power supply 104 is a variable speed drive or motor controller that is configured to selectively provide the electric motor 111 with power.

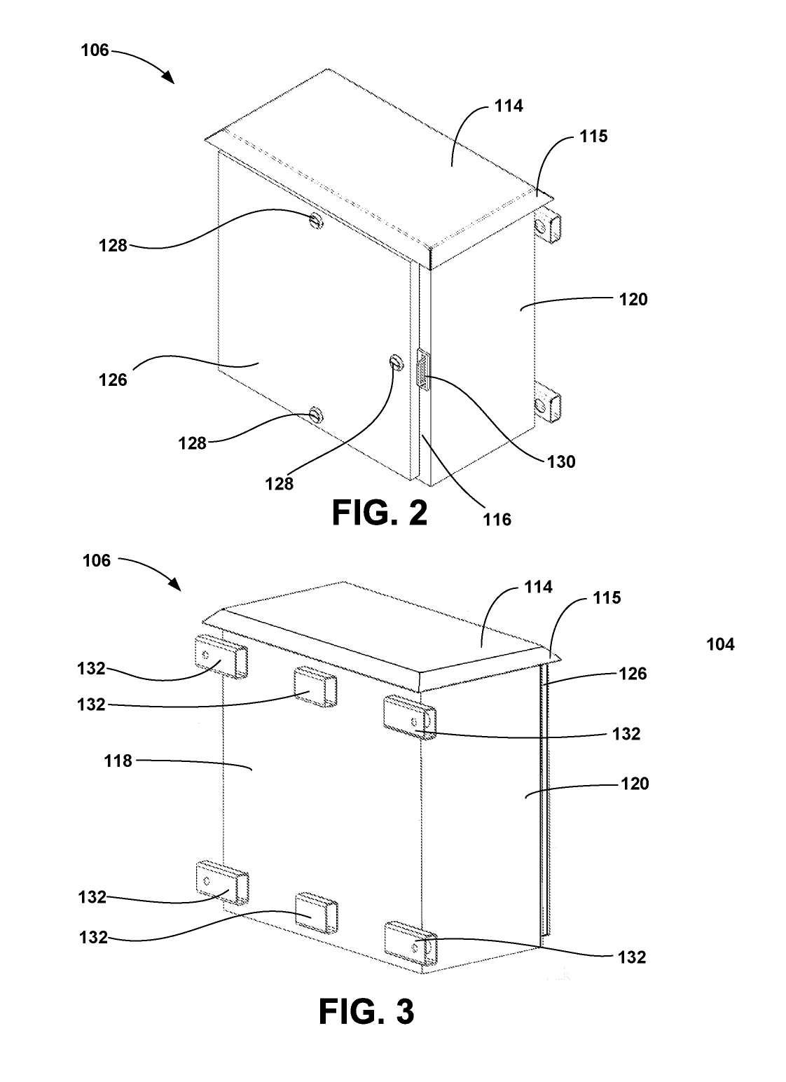

Now turning to FIGS. 2 and 3, shown therein are front and back isometric views, respectively, of a preferred embodiment of the vent box 106 of the present invention. The vent box 106 includes a top 114, a front 116, a back 118, at least two sides 120 and a bottom 122 (not shown in FIGS. 2 and 3) defining an interior 124 of the vent box 106 (not shown in FIGS. 2 and 3). The top 114, front 116, back 118, sides 120 and bottom 122 are preferably constructed from metal and welded or otherwise rigidly fastened together. It will be appreciated that the front 116, back 118 and sides 120 of the vent box 106 may be cooperatively form an enclosure that is generally rectangular, circular, oval or an irregular geometric shape. Thus, as used herein, the term “box” will not be construed to refer only to an enclosure with a rectangular cross-section.

As further depicted in FIG. 2, the front 116 further includes a door 126 providing access to the interior 124 of the vent box 106, one or more latches 128 for securing the door 126, and a padlock mechanism 130 for locking the door 126. Other fastening means known in the art may be used to secure and padlock the door 126, including screws, bolts, hasps, pins and other fasteners. The back 118 of the vent box 106 includes a plurality of brackets 132 for mounting of the vent box 106 onto a variety of surfaces, e.g., on a flat surface or on a pole. According to the present invention, the vent box 106 is constructed in accordance with UL/NEMA 3R Requirements, including for outdoor use, and tested and certified for the following Nationally Recognized Testing Laboratories (“NRTL”) Certified Standards: UL 347:2009; C22.2 No. 253-09; EN 60204-1:2006+A1+AC; EN 60204-11:2000. The latches 128 are NEMA 4 latches. As further depicted in FIGS. 2 and 3, the top 114 includes a weather cap 115 that extends downward over a portion of the front 116, back 118 and sides 120.

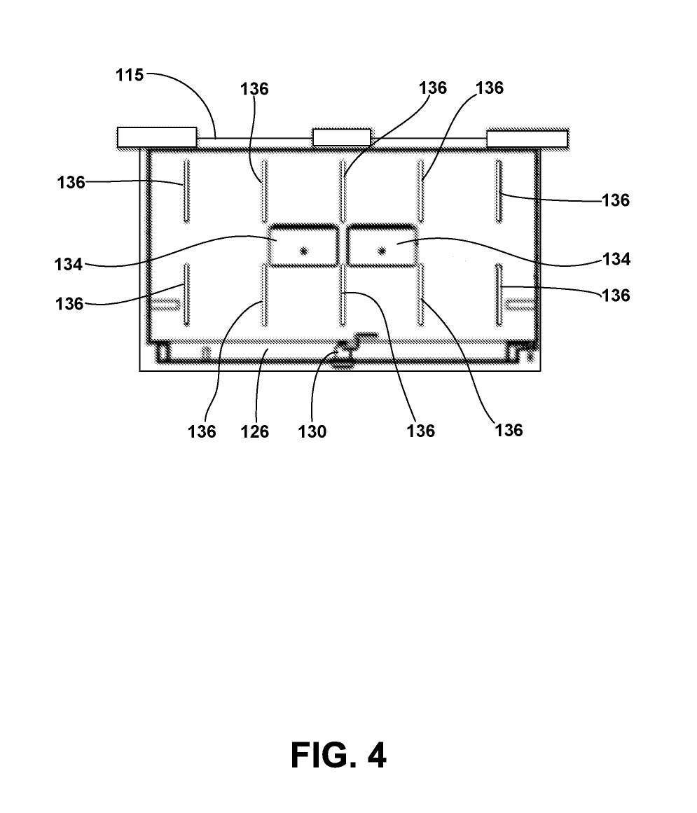

Referring now to FIG. 4, depicted therein is the bottom 122 of the vent box 106. A pair of cable clamps 134 is disposed through the bottom 122 of the vent box 106 for providing strain relief and grounding of the cable 112. The bottom 122 also includes a plurality of lower vents 136 which extend through the bottom 122 to allow gas to vent through the bottom 122 of the vent box 106. In a particularly preferred embodiment, the lower vents 136 are configured as rectangular slots that extend entirely through the bottom 122 of the vent box.

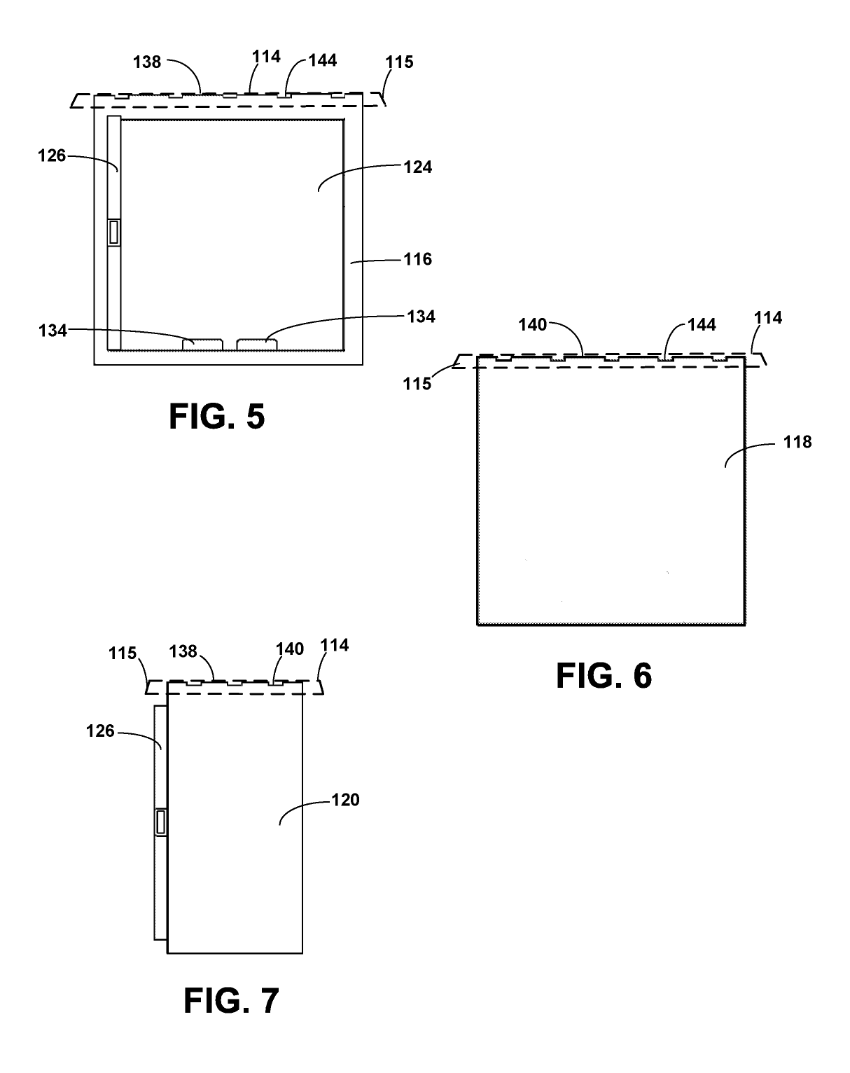

Turning now to FIGS. 5-7, shown therein are a front view, a rear view and a side view, respectively, of the vent box 106. In each of these drawings, the top 114 has been drawn in dashed lines to reveal the elements under the weather cap 115 of the top 114. The front 116, back 118, and sides 120 include, respectively, an upper front edge 138, an upper back edge 140 and upper side edges 142. The vent box 106 includes a plurality of upper vents 144 disposed along one or more of the upper front edge 138, upper back edge 140 and upper side edges 142. Each of the upper vents 144 is preferably configured as a rectangular slot that permits the exchange of gases between the interior 124 of the vent box and the atmosphere. The upper vents 144 are positioned under the weather cap 115 to prevent rain from passing through the upper vents 144 into the interior 124 of the vent box 106. Any rain or other moisture present in the interior 124 is expelled through the lower vents 136. In the particularly preferred embodiment depicted in FIGS. 5-7, the vent box 106 includes upper vents 144 on each of the upper front edge 138, upper back edge 140 and upper side edges 142.

During operation of the downhole pumping system 100, downhole gases often migrate up the cable 112. To prevent gases from igniting and causing explosions from sparks present in the system, the gases must be vented to the atmosphere away from the wellhead 108 and before reaching the power supply 104. Accordingly, the cable 112 is connected to the cable clamps 134 of the vent box 106 to allow for grounding of the cable 112 and strain relief in the interior 124 of the vent box 106. Any gas present on the cable 112 is vented to the atmosphere with lighter gases escaping through the upper vents 140 and heavier gases escaping through the lower vents 136 without the use of any mechanical check valves. The vent box 106 provides for a regulatory approved mechanism of venting gas which is applicable to all field motor installations. In a preferred embodiment, the vent box 106 prevents gas buildup and the vapor-air or gas-air mixtures in concentration above 25% of their lower flammable limit making it a safer alternative during field maintenance.

It is to be understood that even though numerous characteristics and advantages of various embodiments of the present invention have been set forth in the foregoing description, together with details of the structure and functions of various embodiments of the invention, this disclosure is illustrative only, and changes may be made in detail, especially in matters of structure and arrangement of parts within the principles of the present invention to the full extent indicated by the broad general meaning of the terms in which the appended claims are expressed. It will be appreciated by those skilled in the art that the teachings of the present invention can be applied to other systems without departing from the scope and spirit of the present invention.

What is claimed is:

1. A pumping system, wherein the pumping system is configured to recover fluids from a wellbore to surface-based facilities, the pumping system comprising:
a power supply located on the surface;
an electric motor deployed in the wellbore;
a pump driven by the electric motor;
a power cable extending from the power supply to the electric motor; and
a vent box on the power cable between the power supply and the wellhead,
wherein the vent box comprises:
a front, wherein the front has a front upper edge;
a back, wherein the back has a back upper edge;
a pair of opposing sides, wherein each of the pair of opposing sides has a side upper edge;
a bottom connected to the front, the back and the plurality of sides, wherein the bottom includes one or more lower vents that extend through the bottom and place the interior in communication with the atmosphere;
an interior defined by the front, the back, the pair of opposing sides and the bottom;
a plurality of upper vents positioned along the front upper edge, the back upper edge and each of the side upper edges, wherein the upper vents place the interior in communication with the atmosphere; and
a top connected to the front, the back and the pair of opposing sides, wherein the top includes a weather cap that extends downward from the top to partially conceal the plurality of upper vents.

2. The pumping system of claim 1, wherein one of the at least two sides of the vent box further comprises a door for accessing the interior of the vent box, wherein the door further comprises:
one or more latches for securing the door; and
a means for locking the door.

3. The pumping system of claim 1, wherein the vent box further comprises one or more cable clamps extending through the bottom of the vent box to permit the connection of the power cable through the vent box.

4. The pumping system of claim 3, wherein the one or more cable clamps of the vent box are disposed through the bottom and into the interior of the vent box providing a means for grounding the cable and providing strain relief for the cable.

5. The pumping system of claim 1, wherein one of the at least two sides of the vent box further comprises a plurality of brackets for connecting the vent box to a mounting surface.

6. A system for providing power to an electric submersible pumping system deployed in a wellbore, the system comprising:
a surface-based power supply;
an electric motor deployed in the wellbore;
a first power cable connected to the surface-based power supply;
a second power cable connected to the electric motor; and
a vent box connected to the first power cable and to the second power cable,
wherein the vent box comprises:
a front;
a back;
a plurality of sides, wherein two or more of the plurality of sides are connected to the front and the back;
one or more upper vents positioned along an upper edge of at least one of the front, the back or the plurality of sides;
a bottom connected to the front, the back and the plurality of sides, wherein the bottom includes one or more lower vents that extend through the bottom;
a top connected to the front, the back and the plurality of sides, wherein the top includes a weather cap that extends downward from the top to partially conceal the one or more upper vents; and
wherein gases travelling from the wellbore along and inside the second power cable are released through the one or more upper vents and one or more lower vents.

7. The system of claim 6, wherein one of the at least two sides of the vent box further comprises a door for accessing the interior of the vent box, wherein the door further comprises:
one or more latches for securing the door; and
a means for locking the door.

8. The system of claim 6, wherein the vent box further comprises one or more cable clamps extending through the bottom of the vent box to permit the connection of cables through the vent box.

9. The system of claim 8, wherein the one or more cable clamps are disposed through the bottom and into the interior of the vent box providing a means for grounding the cable and providing strain relief for the cable.

10. The system of claim 6 wherein one of the at least two sides of the vent box further comprises a plurality of brackets for connecting the vent box to a mounting surface.

11. A pumping system configured to recover fluids from a wellbore, wherein the pumping system has a surface-based power supply and an electric motor deployed in the wellbore, wherein the pumping system further comprises:
a vent box comprising:
a front;
a back;
a pair of opposing sides;
a bottom;
an interior defined by the front, the back and the pair of opposing sides;
a plurality of upper vents, wherein the vents place the interior in communication with the atmosphere; and
a top connected to the front, the back and the pair of opposing sides, wherein the top at least partially conceals one or more of the plurality of upper vents; and
a first power cable, wherein the first power cable is connected to the vent box and the power supply; and
a second power cable, wherein the second power cable is connected to the electric motor and the vent box; and wherein the first power cable is placed in electrical connection with the second power cable inside the vent box.

12. The system of claim 11, wherein the vent box further comprises one or more cable clamps extending through the bottom of the vent box to permit the connection of cables through the vent box.

13. The system of claim 12, wherein the one or more cable clamps are disposed through the bottom and into the interior of the vent box providing a means for grounding the cable and providing strain relief for the cable.

14. The vent box of claim 11, wherein the vent box further includes a plurality of lower vents extending through the bottom.

15. The vent box of claim 11, wherein the top includes a weather cap that extends downward from the top to partially conceal the plurality of upper vents.
